(19) United States
(12) Patent Application Publication
(10) Pub. No.: US 2026/0359528 A1
(43) Pub. Date: Nov. 12, 2026

(54) FLUID SIMULATION USING A REDUCED SPACE REPRESENTATION

(71) Applicant: Adobe Inc., San Jose, CA (US)

(72) Inventors: Timothy Richard Langlois, Seattle, WA (US); Yixin Chen, Kirkland, WA (US)

(73) Assignee: Adobe Inc., San Jose, CA (US)

(21) Appl. No.: 19/200,963

(22) Filed: May 7, 2025

(51) Int. Cl. G06F 30/28

(52) U.S. Cl. CPC G06F 30/28

(57) ABSTRACT

Fluid simulation techniques using a reduced space representation of a velocity field are described. In one or more examples, input data is received describing a fluid simulation to be generated and a reduced space representation of a velocity field of the fluid simulation is generated based on the input data. The reduced space representation of the velocity field is modified based on a control force defined by the input data. The fluid simulation is then generated for display in a user interface based on the reduced space representation of the velocity field as modified.

### BACKGROUND

Fluid simulations are usable by a computing device to model fluid behavior, such as water, smoke, and air. Fluid simulations find use in a variety of scenarios, such as to enable visual and functional effects in animation and virtual reality applications. However, conventional techniques for generating and controlling fluid simulations are computationally expensive and result in high memory consumption, slow processing times, and are impractical for real-time applications.

### SUMMARY

Techniques and systems are described for generation of a fluid simulation using a reduced space representation. In one or more examples example, a computing device implements a graphics system to generate and control a fluid simulation using a reduced space representation of the velocity field. The graphics system receives input data for the fluid simulation. As part of generating the fluid simulation, the graphics system generates a reduced space representation to represent a velocity field, thereby reducing computational complexity. Based on the input data, the graphics system computes at least one control force using the reduced space representation. The graphics system modifies the reduced space representation by applying the at least one control force. The graphics system then generates the fluid simulation as simulating the velocity field and the at least one control force. The graphics system presents the fluid simulation for display in a user interface.

This Summary introduces a selection of concepts in a simplified form that are further described below in the Detailed Description. As such, this Summary is not intended to identify essential features of the claimed subject matter, nor is it intended to be used as an aid in determining the scope of the claimed subject matter.

### BRIEF DESCRIPTION OF THE DRA WINGS

The detailed description is described with reference to the accompanying figures. Entities represented in the figures are indicative of one or more entities and thus reference is made interchangeably to single or plural forms of the entities in the discussion.

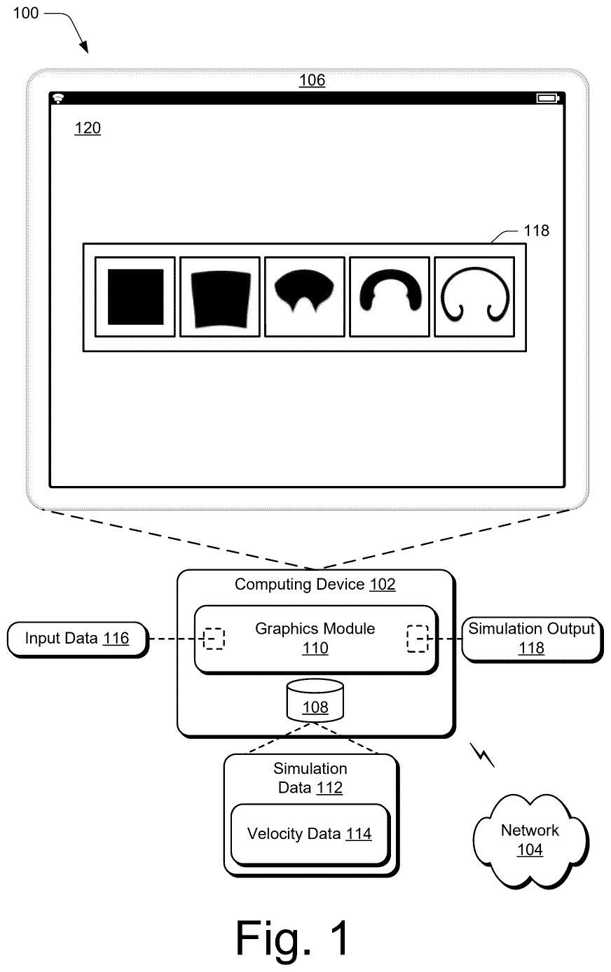

FIG. 1 is an illustration of an environment in an example implementation that is operable to employ digital systems and techniques for fluid simulation using a reduced space representation as described herein.

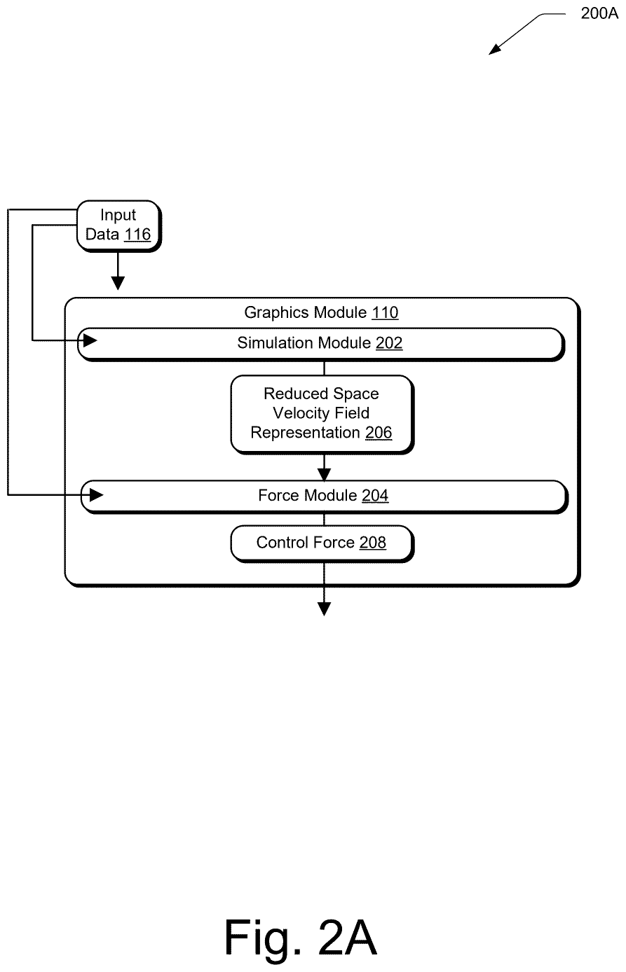

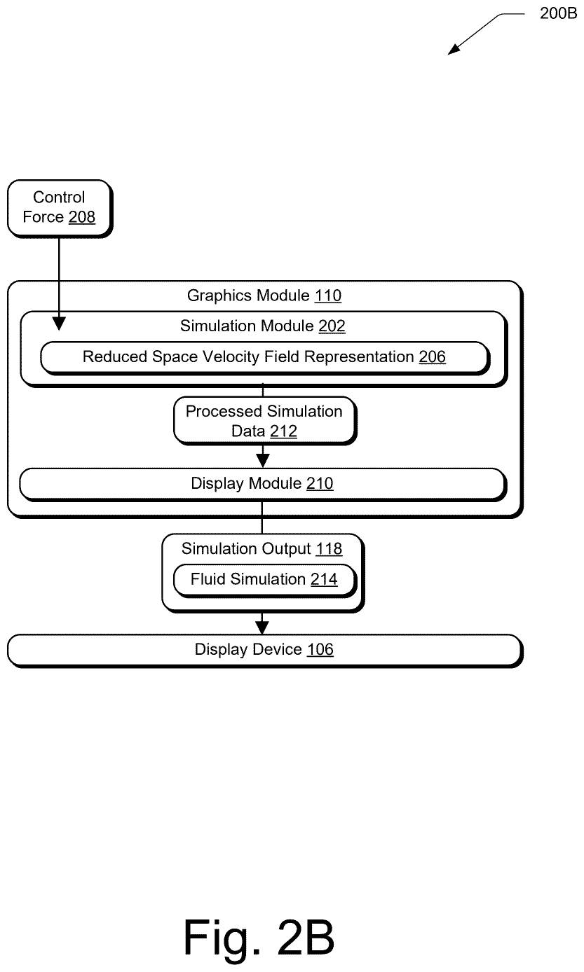

FIG. 2A illustrates a system in an example implementation showing operation of a graphics module for initiating generation of a fluid simulation using a reduced space representation.

FIG. 2B illustrates a system in an example implementation showing operation of a graphics module for generating a fluid simulation using a reduced space representation.

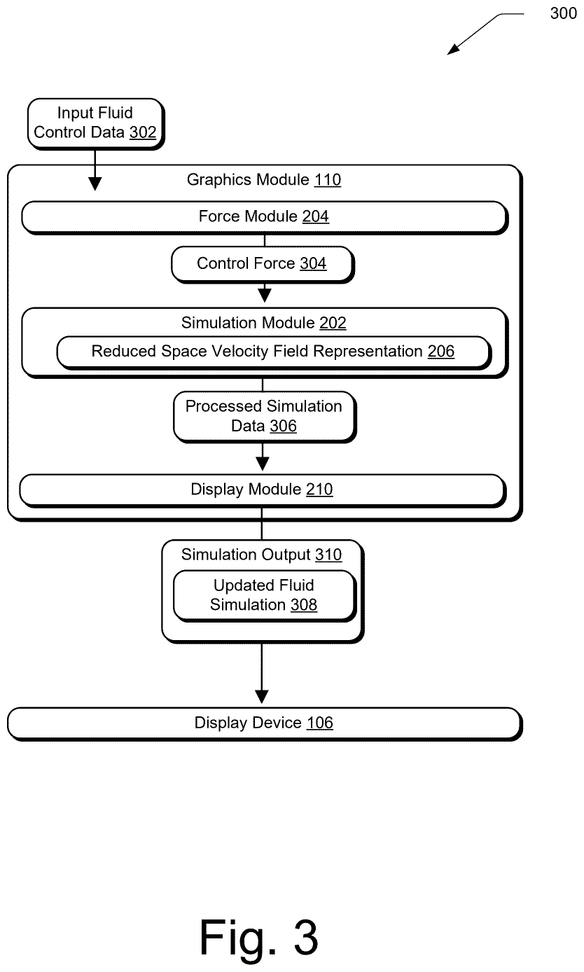

FIG. 3 illustrates a system in an example implementation showing operation of a graphics module for fluid simulation using a reduced space representation.

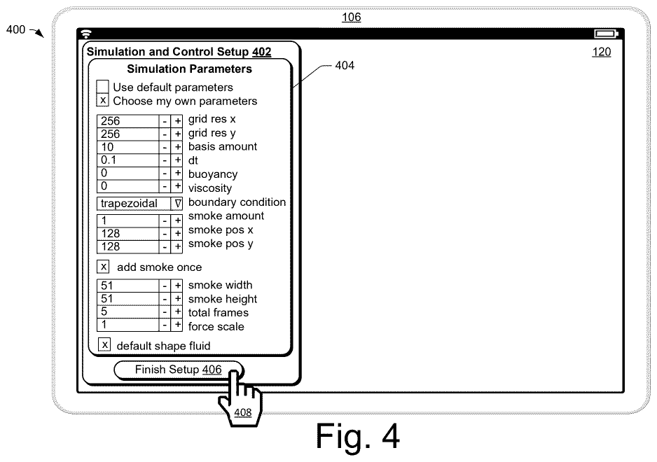

FIG. 4 illustrates an example of receiving input data for a fluid simulation using a reduced space representation.

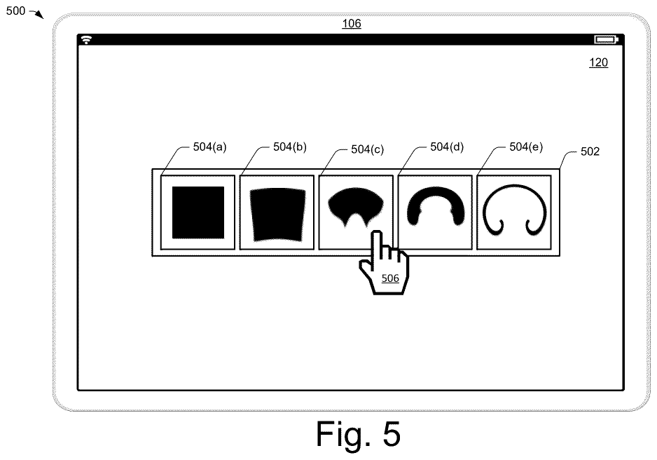

FIG. 5 illustrates an example of a fluid simulation using a reduced space representation based on input data received.

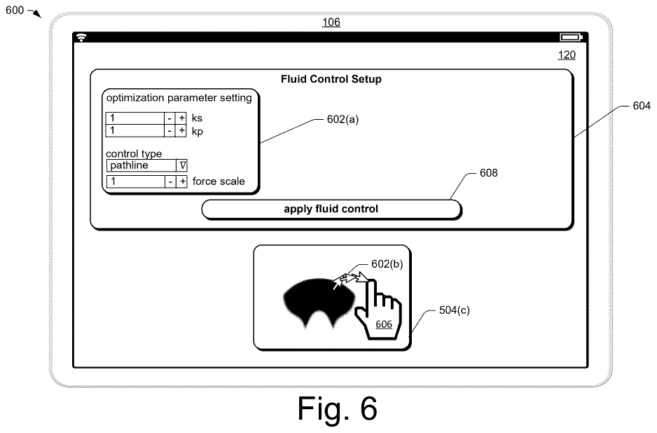

FIG. 6 illustrates an example of receiving fluid simulation input for a fluid simulation using a reduced space representation.

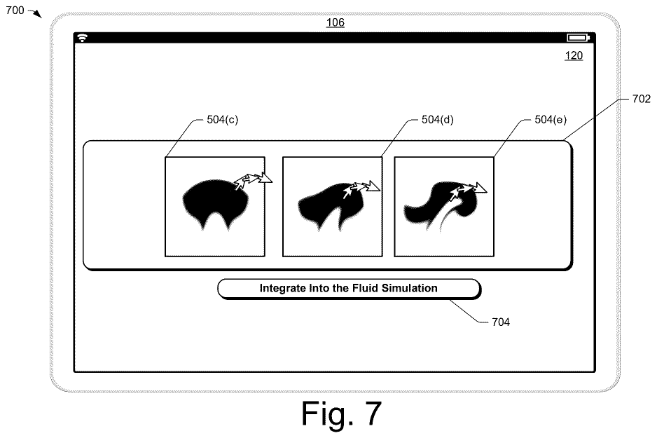

FIG. 7 illustrates an example of modifying a fluid simulation using a reduced space representation, responsive to fluid simulation input received.

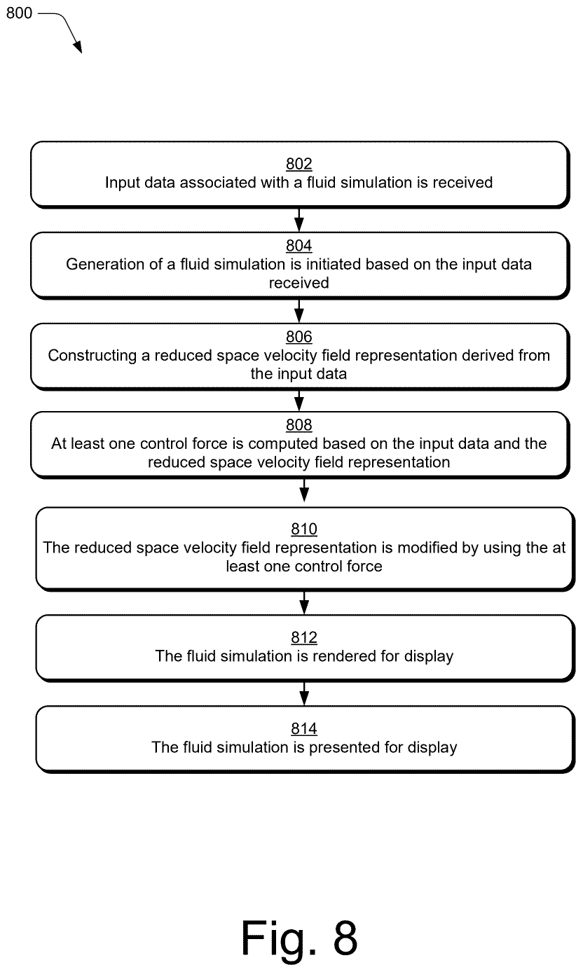

FIG. 8 illustrates a flow diagram depicting a procedure in an example implementation for fluid simulation using a reduced space representation.

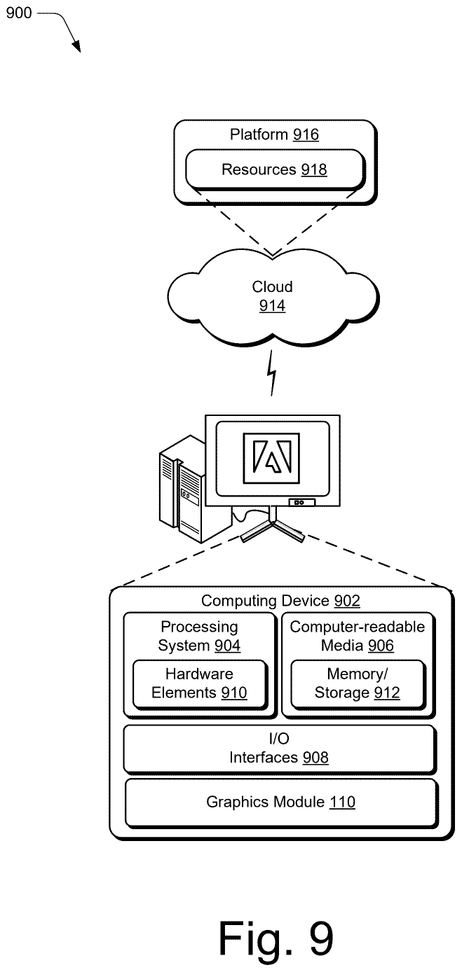

FIG. 9 illustrates an example system that includes an example computing device that is representative of one or more computing systems and/or devices for implementing the various techniques described herein.

### DETAILED DESCRIPTION

### Overview

Conventional techniques for generating a fluid simulation by a computing device often rely on complex and computationally expensive calculations due to the highly nonlinear nature of fluid behavior and the large degrees of freedom, as each portion of the simulated fluid moves independently. For instance, some of the conventional techniques solve full Navier-Stokes equations across a dense simulation grid, leading to vast memory usage and long computation times. This makes real-time feedback nearly impossible, causing users to wait minutes or hours for results, which severely limits iterative refinement. Because of the large computational demands, the conventional techniques for generating fluid simulations fail to enable real-time responsiveness for actualizing artistic or functional visions of users.

Even more recent conventional techniques for generating and controlling fluid simulations, such as deep-learning-based approaches, present their own challenges. Deep-learning-based approaches often lack interpretability, preventing users from making direct adjustments to the simulated fluid. Due to training data constraints, deep-learning-based approaches fail to generalize to new scenarios, resulting in limited capabilities. As a result, even deep-learning-based fluid simulation techniques lack effective real-time interactive fluid simulation, and often use significant computational resources.

In contrast, the described techniques and systems for generation of a fluid simulation using a reduced space representations addresses the issues of the conventional techniques. To do so, the reduced space representation is used of a velocity field instead of using a full space, high-dimensional velocity field, substantially reducing computational complexity. In some examples, the described techniques and systems express the velocity field as a weighted sum of precomputed eigenfunctions. These described techniques and system for fluid simulation using a reduced space representation not only ensure real-time responsiveness but also enable effective interactive control of simulated fluid.

For example, Alice, a user, wants to simulate a controlled water fountain. Alice provides input data, specifying two keyframes representing a shape of water streams at two points in time, for a total of five frames, velocity constraints to ensure the water streams rise and arc outward, and obstacle constraints to enforce a no-slip condition at the fountain base. Responsive to receiving the input data, the system initiates fluid simulation generation. A computing device constructs a reduced space representation of a velocity field (e.g., by using one or more Laplacian eigenfunctions), reducing computational complexity while preserving realistic fluid motion. Based on the input data, the computing device then computes control forces to guide the water streams along Alice's keyframed paths over five frames and integrates the control forces over time, ensuring the velocity constraints are applied as the simulated water streams rise and fall. The computing device then renders and outputs the fluid simulation for display.

As the fluid simulation evolves responsive to receiving additional input data, the computing device dynamically updates the velocity field (e.g., in real-time) while Alice refines the fluid simulation. The computing device processes and displays the updated fluid simulation in real-time using the reduced space representation, enabling Alice to make fluid simulation adjustments efficiently and interactively. Once Alice finalizes the design of the fluid simulation, the computing device reconstructs the reduced field representation of the velocity field as a full space representation, resulting in a high-resolution representation suitable for export. The computing device then outputs the completed fluid simulation. This approach ensures efficient, interactive fluid simulation in real time, enabling control of fluid motion without the computational overhead of conventional fluid simulation techniques.

In the following discussion, an example environment is first described that employs examples of techniques described herein. Example procedures are also described which are performable in the example environment and other environments. Consequently, performance of the example procedures is not limited to the example environment and the example environment is not limited to performance of the example procedures.

### Example Fluid Simulation Environment

FIG. 1 is an illustration of an environment 100 in an example implementation that is operable to employ digital systems and techniques for fluid simulation using a reduced space representations as described herein. The illustrated environment 100 includes a computing device 102 connected to a network 104. The computing device 102 is configurable as a desktop computer, a laptop computer, a mobile device (e.g., assuming a handheld configuration such as a tablet or mobile phone), and so forth. Thus, the computing device 102 is capable of ranging from a full-resource device with substantial memory and processor resources (e.g., personal computers and game consoles) to a low-resource device with limited memory and/or processing resources (e.g., mobile devices). In some examples, the computing device 102 is representative of a plurality of different devices, such as multiple servers utilized to perform operations “in the cloud.”

The illustrated environment 100 also includes a display device 106 that is communicatively coupled to the computing device 102 via a wired or wireless connection. Various device configurations are usable to implement the computing device 102 and/or the display device 106. The computing device 102 includes a storage device 108 and a graphics module 110. The storage device 108 is illustrated to include simulation data 112 and velocity data 114.

The simulation data 112 represents data (e.g., numerical or configuration data) usable to define, execute, or store simulations, including fluid simulations. Examples of the simulation data 112 include interactable user interface elements for modifying or generating simulations, the velocity field data 114, initial conditions for simulations (e.g., via simulation parameters), processed simulation results, fluid properties, control forces, boundary conditions, fluid constraints, or keyframe constraints defining how a simulated fluid behaves over time. The graphics module 110 uses the simulation data 112 to generate fluid simulations and to modify the fluid simulations. Examples of initial simulation parameters include grid resolution, simulation timestep, or viscosity.

Examples of fluid properties include fluid density distribution at a point in time, temperature variation, and so forth. Keyframe constraints include a number of frames for interpolation, a speed of transition from one keyframe to a second keyframe, and so forth. Examples of boundary conditions include a density of an obstacle, a size of an obstacle, and a location of an obstacle. Examples of the simulation data 112 include predefined simulation models, discretized equation coefficients, solver parameters, governing equations, basis function weights, velocity field representations, precomputed Laplacian eigenfunctions, fluid simulation states defining a behavior of a simulated fluid over time, kinematic equations, density data, force data, and so forth.

The velocity data 114 refers to data pertaining to modeling, constructing, representing, or storing velocity content or velocity values, such as velocity fields. Examples of the velocity field data 114 include computed velocity field representations (e.g., reduced-space velocity field representations), full-space velocity field representations, a velocity field expressed as a set of weighted Laplacian eigenfunctions, velocity fields at different timesteps, and so forth.

The graphics module 110 utilizes the fluid simulation data 112 to generate and manipulate fluid simulations based on the fluid simulation data 112, with adjustable properties such as density and global forces such as gravity and wind. The graphics module 110 is illustrated as having, receiving, and/or transmitting input data 116. The input data 116 represents inputs for configuring a fluid simulation. Examples of the input data includes simulation constraints (e.g., pathline constraints), external environmental forces, frames (e.g., keyframes), digital content for the fluid simulation, target states for the fluid simulation, fluid properties, fluid simulation parameters, resolution settings (e.g., adaptive resolution), grid settings, basis amount, time increment per simulation step, buoyancy, boundary settings, collision settings, emission settings, frame properties (e.g., a number of frames), visualization parameters, and so forth. In some examples, the input data 116 includes one or more digital artworks.

The input data 116, in some examples, describes user interactions received via a user interface 120 for generating and applying the simulation data 112. For example, the user interface 120 is configurable for editing digital content (e.g., fluid simulations), and the digital content (e.g., a simulation output 118) is displayed in the user interface of the application. Examples of the simulation output 118 include simulations (e.g., fluid simulations), visualizations corresponding to the fluid simulation such as velocity field visualizations, particle-based representations of simulated fluid, simulated fluid, interpolated frames, visualizations of control forces, pressure distribution maps, interactive previews of simulated fluid, visualizations of external forces, keyframe-based transformations, pathline representations, rendered animations, volumetric data, velocity field representations, and so forth.

### Fluid Simulation Using a Reduced Space Representation

The following discussion describes techniques that are implementable utilizing the previously described systems and devices. Aspects of each of the procedures are implemented in hardware, firmware, software, or a combination thereof. The procedures are shown as a set of blocks that specify operations performed and/or caused by one or more devices and are not necessarily limited to the orders shown for performing the operations by the respective blocks.

FIG. 2A illustrates a system 200A in an example implementation showing operation of the graphics module 110 of FIG. 1 in greater detail as initiating generation of a fluid simulation 214 with reduced space representations. The graphics module 110 is illustrated to include a simulation module 202 and a force module 204.

The graphics module 110 receives the input data 116. Examples of the input data 116 include digital content for one or more frames or keyframes, fluid properties, domain size, domain resolution, initial velocity distributions, initial density distributions, external forces, boundary conditions, obstacle configurations, and so forth. The graphics module 110 communicates the input data 116 to the simulation module 202 and the force module 204.

The simulation module 202 receives the input data 116. The simulation module 202 is configured to perform operations pertaining to simulations (e.g., fluid simulations), examples of which include receiving data pertaining to fluid simulations (e.g., the input data 116), processing data pertaining to fluid simulations, initiating generating of the simulation output 118 (e.g., fluid simulations), generating simulation output 118 (e.g., fluid simulations), modifying fluid simulations, leveraging the simulation data 112, computing control forces for fluid simulations, representing velocity fields, rendering fluid simulations, and outputting fluid simulations. Responsive to receiving the input data 116, the simulation module 202 initiates generation of a fluid simulation based on the input data 116.

Based on the input data 116, the simulation module 202 constructs a reduced space representation of a velocity field of the fluid simulation 214, illustrated as a “reduced space velocity field representation 206/” as. In some examples, the simulation module 202 leverages a governing equation of the simulation data 112—

$$u = {\sum }_{k = 1}^{r} {w}_{k} {ψ}^{k} = U w$$

—to construct the reduced space velocity field representation 206 using a Laplacian eigenfunction basis.

$$u = {\sum }_{k = 1}^{r} {w}_{k} {ψ}^{k} = Uw$$

defines how the velocity field u is represented in a reduced dimensional space. Instead of storing velocity values at every grid point in full space, the simulation module 202 expresses the velocity field as a weighted sum of basis functions ψ^{k}.

In some examples, the basis functions are Laplacian eigenfunctions. The coefficients wₖ determine how much each basis function contributes to the overall velocity field. The coefficients wₖ define a fluid motion instead of storing velocity at each grid point. The term U is a matrix containing the basis functions, and w is a vector of weight coefficients. By using this basis function representation, the graphics module 110 reduces the number of degrees of freedom needed to model or simulate motion of simulated fluids, resulting in substantial computational savings while maintaining accurate modeling of the simulated fluids with the reduced space velocity field representation 206. In some examples, the simulation module 202 encodes a density field within the reduced space representation. The simulation module 202 communicates the reduced space velocity field representation 206 to the force module 204.

The force module 204 receives the reduced space velocity field representation 206 from the simulation module 202 and the input data 116 from the graphics module 110. The force module 204 is configured to perform operations pertaining to control forces for fluid simulations, including computing an optimal number of control forces for shaping the fluid simulation, computing one or more control forces, e.g., illustrated at least one control force 208. The force module 204 computes at least one control force 208 based on the input data 116 and the reduced space velocity field representation 206.

In some examples, the force module 204 computes the control forces 208 (e.g., f^{t}) by minimizing an objective function that configures the fluid simulation to follow user-defined keyframes while maintaining physical accuracy as follows:

$$φ ( f , q ) = {k}_{s} {\sum }_{t = 0}^{n} {‖ {f}^{t} ‖}^{2} + {k}_{w} {\sum }_{t ∈ {K}_{w}} {‖ {w}^{t} - {w}^{t *} ‖}^{2} + {k}_{d} {\sum }_{t ∈ {K}_{d}} {‖ {a}^{t} - {a}^{t *} ‖}^{2} .$$

In some implementations, as part of the computing of the control forces 208, the force module 204 computes a gradient of the objective function with respect to the control forces 208 via

$$\frac{d φ}{df} = {r}^{T} \frac{\partial s}{\partial f} + \frac{\partial φ}{\partial f} .$$

The gradient

$$\frac{d φ}{df}$$

is computable using both direct derivatives of the objective function and the sensitivity of the system state to control forces. The term

$$\frac{\partial s}{\partial f}$$

represents how changes in the control forces 208 affect a system state. By computing the gradient of the objective function, the control forces 208 are substantially improved as compared to the conventional techniques for computing control forces because the gradient of the objective function enables the graphics module 110 to determine how small changes in control forces affect the fluid simulation. The force module 204 communicates the at least one control force 208 to the simulation module 202. In the context of generating the fluid simulation, consider next FIG. 2B.

FIG. 2B illustrates a system 200B in an example implementation showing operation of the graphics module 110 of FIG. 1 in higher detail as generating a fluid simulation 214 with reduced space representations. The graphics module 110 is illustrated to include the simulation module 202 of FIG. 2A and a display module 210.

The simulation module 202 receives the at least one control force 208 from the force module 204 of FIG. 2A. The simulation module 202 modifies the reduced space velocity field representation 206 by applying the at least one control force 208. In some examples, the simulation module 202 modifies the reduced space velocity field representation 206 by modifying weight coefficients with the at least one control force, which modify the reduced space velocity field representation 206.

In some examples, the simulation module 202 modifies the reduced space velocity field representation 206 based on the at least one control force 208 via the following integration:

$${w}^{*} = ( \frac{Δ t}{2} {C}^{*} {w}^{*} + \frac{Δ t}{2} {C}^{t} {w}^{t} + {w}^{t} + {f}^{t} ) , {w}^{t + 1} = D {w}^{*} .$$

By using the integration, the simulation module 202 modifies the reduced space velocity field representation 206 to integrate the at least one control force 208 as part of the fluid simulation 214.

The simulation module 202 communicates processed simulation data 212 corresponding to the fluid simulation 214, the reduced space velocity field representation 206, and the at least one control force 208 to the display module 210.

The display module 210 receives the processed simulation data 212 from the simulation module 202. The display module 210 is configured to perform operations pertaining to rendering and displaying fluid simulation content, such as the fluid simulation 214, the simulation output 118, the reduced space velocity field representation 206, or the at least one control force 208. Based on the processed simulation data 212, the display module 210 renders the simulation output 118 including the fluid simulation 214.

In some examples independent of a control force 208, the display module 210 renders and outputs the simulation output 118 including the fluid simulation 214. In some examples, in which the input data 116 includes a first digital artwork and a second digital artwork, the fluid simulation 214 rendered includes an interpolation from the first digital artwork and the second digital artwork.

The display module 210 communicates the simulation output 118 including the fluid simulation 214 to the display device 106 for display. In the context of the simulation output 118 and the fluid simulation 214, consider next FIG. 3.

FIG. 3 illustrates a system 300 in an example implementation showing operation of the graphics module 110 of FIG. 1 in higher detail for fluid simulation using a reduced space representation. In this example implementation, the graphics module 110 includes the force module 204, the simulation module 202, and the display module 210 of FIGS. 2A and 2B.

The force module 204 of the graphics module 110 receives the input fluid simulation data 302. The input fluid simulation data 302 represents data pertaining to a fluid simulation modification for fluid simulations (e.g., the fluid simulation 214) or simulated fluids. In this illustrated system 300, graphics module 110 uses the input fluid simulation data 302 to modify the fluid simulation 214 of FIG. 2B to render and output an updated version of the simulation output (the “simulation output 310”) or an updated version of the fluid simulation (the “updated fluid simulation 308”).

Examples of types of fluid simulation input data include keyframe constraints, pathline constraints, velocity constraints, obstacle constraints, external force constraints, vorticity constraints, symmetry constraints, density constraints, and interactive constraints.

Keyframe constraints force the fluid to match predefined shapes or states at specific moments in time. Pathline constraints ensure that fluid particles follow designated trajectories throughout the simulation. Velocity constraints restrict the motion of the fluid to specific directions, magnitudes, or patterns. Obstacle constraints enforce boundary conditions such as no-slip or free-slip behavior when the fluid interacts with solid objects.

External force constraints apply forces such as wind, gravity, or explosions to influence the motion and behavior of the fluid. Vorticity constraints preserve or modify swirling motion in the fluid to maintain or enhance rotational flow structures. Symmetry constraints ensure that the fluid behaves in a mirrored fashion across a defined axis or plane. Density constraints control the spatial and temporal distribution of fluid density to achieve desired visual or physical effects. Interactive constraints enable real-time user input to dynamically modify a simulated fluid's motion or behavior for simulations.

Examples of the input fluid simulation data 302 include keyframe definitions, pathline definitions, velocity constraints, obstacle interactions, external force parameters, vorticity adjustments, symmetry constraints, density distribution specifications, and so forth. Keyframe definitions specify target fluid shapes at specific frames, ensuring the fluid transitions smoothly between predefined states. Pathline definitions provide particle trajectories for the fluid to follow, guiding elements such as smoke or water along a controlled path. Velocity constraints restrict fluid motion in designated directions.

Obstacle interactions define how the fluid behaves near solid boundaries, enforcing no-slip or free-slip conditions depending on the material properties. External force parameters apply wind, gravity, or explosions to influence fluid motion, allowing for realistic environmental effects. Vorticity adjustments modify rotational flow behavior, enhancing swirling patterns in turbulent fluid simulations. Symmetry constraints enforce mirrored fluid motion across an axis, ensuring consistent movement of the simulated fluid. Density distribution specifications control fluid density over time, allowing for gradual dissipation or concentration in fluid effects. The graphics module 110 communicates the input fluid simulation data 302 to the simulation module 202 and the force module 204.

The force module 204 receives the input fluid simulation data 302. The force module 204 computes at least one control force 304 based at least in part on the input fluid simulation data 302. In some examples, the force module 204 computes the at least one control force 304 in real-time. In some implementations, as part of computing the at least one control force 304, the force module 204 computes or recomputes a gradient of the objective function to account for the input fluid simulation data 302 via

$${r}^{t} = {( \frac{\partial {s}^{t}}{\partial {q}^{t}} )}^{T} {r}^{t + 1} + {( \frac{\partial φ}{\partial {q}^{t}} )}^{T} .$$

By computing or recomputing the gradient of the objective function to account for the input fluid simulation data 302, the force module 204 aligns the one or more control forces 304 of the fluid simulation 214 with the input fluid simulation data 302 and propagates control influence backward in time.

In some examples, the force module 204 computes the control forces 304 (e.g., f^{t}) by minimizing the objective function that configures the fluid simulation 214 to follow user-defined keyframes while keeping physical accuracy:

$$φ ( f , q ) = {k}_{s} {\sum }_{t = 0}^{n} {‖ {f}^{t} ‖}^{2} + {k}_{w} {\sum }_{t ∈ {K}_{w}} {‖ {w}^{t} - {w}^{t *} ‖}^{2} + {k}_{d} {\sum }_{t ∈ {K}_{d}} {‖ {a}^{t} - {a}^{t *} ‖}^{2} .$$

The force module 204 is configured to compute the at least one control force 304 in various ways based on a type of the input fluid simulation data 302, as discussed throughout. The following discussion describes techniques for fluid simulation using a reduced space representation via pathline constraints. In some examples, the pathline constraints provide a visualization of how portions of the simulated fluid (e.g., for the updated fluid simulation 308 of the fluid simulation 214) move over time or over frames. In some examples, the force module 204 adds particle control of the simulated fluid (e.g., of the updated fluid simulation 308 of the fluid simulation 214) by augmenting a state q^{t}=[w^{t}, a^{t}, p^{t}]^{T} with a position each particle. The fluid simulation module 204 integrates the each particle through fluid flow of the fluid simulation 214 or the updated fluid simulation 308, and the force module 204 augments the cost function with ξₚ=kₚ Σ_{t∈K}_{ₚ}∥p^{t}−p^{t*}∥².

The following discussion describes obstacle techniques for fluid simulation using a reduced space representation. Conventional techniques for obstacles in fluid simulation are often handled by a simple projection technique, in which the full space velocity field is reconstructed, unwanted velocity components are subtracted out, then the velocity field is transformed back to the reduced space. Instead, the force module 204 adapts a cost function to handle obstacles such that constraints (e.g., obstacle constraints) are treated in a soft manner.

In some examples, responsive to receiving obstacle data as part of the input fluid simulation data 302, the force module 204 uses the following equations:

$${u}_{x}^{*} = \{ \begin{matrix}0 , & x is not in an obstalce \\ \hat{n} , & x is on the boundary of an obstacle \\ {u}_{x} , & x is inside of an object\end{matrix}$$

$${ξ}_{o} = {k}_{o} {\sum }_{x} {( {u}_{x} - {u}_{x}^{*} )}^{2} .$$

The equations provided above ensure that motion of the simulated fluid of the simulation output 310 adheres to boundaries defined by the obstacle data. The first equation defines a target velocity

$${u}_{x}^{*} ,$$

based on whether a point x is inside, outside, or on a boundary of the obstacle of the obstacle data. The force module 204 penalizes deviation from the target velocity by using the second equation. The penalty term ξₒ ensures that the simulated fluid does not flow through obstacles, therefore preserving physical accuracy.

The following discussion describes multi-resolution pyramid techniques for fluid simulation using a reduced space representation. When a keyframe received by the force module 204 as part of the input data 116 or the input fluid simulation data 302 is far from a current state of the fluid simulation 214, the L₂ cost function can break down, resulting in zero gradients. To avoid this, in some examples, the force module 204 optimizes based on a sequence of density resolutions. The force module 204 optimizes on a low-resolution image until convergence and then uses that solution to initialize the optimization at a next level for the simulation output 310. In some examples, the velocity degrees of freedom do not change and are expressed on different resolution grids by the simulation module 202.

The force module 204 communicates the at least one control force 304 to the simulation module 202. The simulation module 202 receives the at least one control force 304 from the force module 204. The simulation module 202 modifies the reduced space velocity field representation 206 by applying the at least one control force 304. In this way, one or more properties of the simulated fluid are updated efficiently without reconstructing the velocity field. In some examples, the reduced space velocity field representation 206 remains in reduced space, such that the weights are updated, solely, based on the at least one control force 304, and the basis functions (e.g., the Laplacian eigenfunctions) remain the same.

In some examples, the simulation module 202 modifies the reduced space velocity field representation 206 by modifying the weight coefficients with the at least one control force 304, which modify the reduced space velocity field representation 206. In some examples, the simulation module 202 modifies the reduced space velocity field representation 206 based on the at least one control force 304 via the following integration:

$${w}^{*} = ( \frac{Δ t}{2} {C}^{*} {w}^{*} + \frac{Δ t}{2} {C}^{t} {w}^{t} + {w}^{t} + {f}^{t} ) , {w}^{t + 1} = D {w}^{*} .$$

By using the integration, the simulation module 202 updates the reduced space velocity field representation 206 to integrate the at least one control force 304 as part of the updated fluid simulation 308. In some implementations, the simulation module 202 modifies the velocity field of the reduced space velocity field representation 206 forward in time via an implicit update scheme, such as an implicit trapezoidal integration. In some implementations, the simulation module 202 advances the velocity field of the reduced space velocity field representation 206 by using an implicit trapezoidal integration.

In some examples, the simulation module 202 modifies the velocity field of the reduced space velocity field representation 206 by using a damping function accounting for viscosity. In some implementations, the simulation module 202 uses frequency-based filtering as part of modifying the velocity field of the reduced space velocity field representation 206.

The simulation module 202 outputs processed simulation data 306 corresponding to the updated fluid simulation 308, the reduced space velocity field representation 206 updated, and the at least one control force 304 to the display module 210. The display module 210 receives the processed simulation data 306 from the simulation module 202. The display module 210 is configured to perform operations pertaining to rendering and displaying fluid simulation content, such as the updated fluid simulation 308, the simulation output 310, the reduced space velocity field representation 206 updated, or the at least one control force 304. Based on the processed simulation data 306, the display module 210 renders the simulation output 310 including the updated fluid simulation 308.

The display module 210 communicates the simulation output 310 including the updated fluid simulation 308 to the display device 106 for display. In some examples, the display module 210 renders and outputs the simulation output 310 in real-time for display. In some implementations, the fluid simulation includes digital content visualizing the simulated fluid over time. In the context of fluid simulation using a reduced space representation, consider next frequency control techniques described below.

The following discussion describes frequency control techniques for fluid simulation using reduced space representations. Due to the high non-linearity of fluid simulation, there are many local minima. Laplacian eigenfunctions support improved frequency control through reweighting of an advection tensor. In some examples, the simulation module 202 uses a cascade of low-pass filters (e.g., ideal low pass filters), which limits the number of basis functions.

Rather than filtering frequency content of the control forces (e.g., the control force 304) at different stages of optimization, solely, the simulation module 202 reduces the degrees of freedom of the system, making optimization substantially faster at lower frequencies. In the context of fluid simulation using a reduced space representation, consider next FIG. 4.

FIG. 4 illustrates an example 400 of receiving the input data 116 via user input 408 for initiating generation of a fluid simulation using a reduced space representation. This example 400 includes the display device 106 including the user interface 120 of FIG. 1. The user interface 120 includes a simulation and control setup window 402, input data 404, and a selectable element 406. The user interface 120 is configured to receive the input data 404 via the user input 408.

In this example 400, the input data 116 includes simulation parameters, including a grid resolution (grid res x and y, both set at 256), a basis amount for the reduced space representation, a simulation time step (dt set at 0.1), buoyancy, viscosity, and boundary conditions (“trapezoidal”). The input data 116 includes initial conditions for a fluid (smoke), including a fluid amount (smoke amount), an initial position of the fluid (smoke pos x and y set at 128), dimensions of the fluid (width and height set at 51), and a total number of frames for the simulation.

An option to add a fluid once (“add smoke once”) is activated, meaning the fluid (the smoke) is introduced at the beginning of the simulation. The input data 404 includes a force scale setting and a fluid shape selection. In this example 400, the input data 116 specifies that the force scale is set to one and that a default shape is selected for the simulation. The selectable element 406 is selectable via the user input 408 to initialize generation of the simulation. Responsive to receiving the input data 116, the graphics module 110 communicates the input data 116 to simulation module 202 and the force module 204 for generating the fluid simulation 502 by using the input data 116. In the context of the fluid simulation 502, next consider FIG. 5.

FIG. 5 illustrates an example 500 of a fluid simulation 502 with reduced space representations based on input data 116. This example 400 includes the display device 106 including the user interface 120 of FIG. 1. The user interface 120 includes the fluid simulation 502, including frames 504(a)-504(e) (as a sequence of frames 504), in which the frames 504(a)-504(e) depict a simulated fluid generated based on the input data 116 including the simulation parameters of FIG. 4. In some examples, the user interface includes one or more user-adjustable controls for the fluid simulation 502 (e.g., the updated fluid simulation 308) or the simulation output 310.

The fluid simulation 502 integrates the grid resolution (grid res x and y, both set at 256), the simulation time step (dt set at 0.1), the buoyancy parameter, the viscosity parameter, the trapezoidal boundary condition, the smoke condition for the simulated fluid, the smoke amount, the initial position of the smoke (pos x and y at 128), the dimensions of the fluid (width of 51 and the height of 51), the total number of 5 frames for the fluid simulation 502, the introduction of the smoke at the beginning of the fluid simulation 502, the force scale of 1 for the smoke, and the default fluid shape of a square.

Each frame depicts the fluid shape of the simulated fluid at a respective stage of the fluid simulation 502. As illustrated, the user selects (e.g., via user input 506) frame 504(c) (i.e., the third frame) from the sequence of frames 504. Responsive to receiving the user input 506, the graphics module 110 initiates configuration of fluid simulation settings via input fluid simulation data 302. In the context of receiving input fluid simulation data 302, next consider FIG. 6.

FIG. 6 illustrates an example 600 of receiving the fluid simulation input data 302 (e.g., fluid simulation setup data 602(a) and pathline constraint data 602(b)) for the fluid simulation 502 with reduced space representations. This example 400 includes the display device 106 including the user interface 120 of FIG. 1. The user interface 120 includes a window 604 configured to receive the fluid simulation input data 302 and the frame 504(c) from FIG. 5.

The user interface 120 is configured to receive the input fluid simulation data 302, including the fluid simulation setup data 602(a) and the pathline constraint data 602(b). In this example 400, the fluid simulation setup data 602(a) includes optimization parameters (ks and kp, both set to 1 via the user input 606), a “pathline” control type, and a force scale of 1. Via the user input 606, the user places pathline constraint points representative of the pathline constraint data 602(b) directly onto the depicted simulated fluid of the frame 504(c), defining a trajectory along which fluid particles of the simulated fluid should move under the force scale of 1. After specifying the pathline constraint via the pathline constraint data 602(b), the user selects a selectable element 608 (an “apply fluid simulation” button), initiating the fluid simulation using a reduced space representation, based on the received input fluid simulation data 302.

FIG. 7 illustrates an example 700 of modifying the fluid simulation 502 with reduced space representations based the fluid simulation input data 302 including the fluid simulation setup data 602(a) and pathline constraint data 602(b) received. This example 700 includes the display device 106 including the user interface 120 of FIG. 1. The user interface 120 includes a preview 702 (e.g., as part of the simulation output 310) of frames 504(c) (frame 3), 504(d) (frame 4), and 504(e) (frame 5).

The preview 702 includes three consecutive frames that illustrate the fluid simulation's 502 progression under the applied pathline constraint. Each successive frame demonstrates the fluid shape evolving and following the trajectory defined by the user's earlier pathline constraint data 602(b). The optimization parameters (ks, kp, control type as “pathline,” and force scale) remain consistent with the fluid simulation setup data 602(a) of FIG. 6. A selectable element 704 labeled “Integrate Into the Fluid Simulation” is displayed via the user interface 120, enabling the user to incorporate the fluid simulation modifications into the ongoing fluid simulation 502 dynamically, in real time.

In general, functionality, features, and concepts described in relation to the examples above and below are employed in the context of the example procedures described in this section. Further, functionality, features, and concepts described in relation to different figures and examples in this document are interchangeable among one another and are not limited to implementation in the context of a particular figure or procedure. Moreover, blocks associated with different representative procedures and corresponding figures herein are applicable individually, together, and/or combined in different ways. Thus, individual functionality, features, and concepts described in relation to different example environments, devices, components, figures, and procedures herein are usable in any suitable combinations and are not limited to the particular combinations represented by the enumerated examples in this description.

### Example Procedures

The following discussion describes techniques which are implementable utilizing the previously described systems and devices. Aspects of each of the procedures are implementable in hardware, firmware, software, or a combination thereof. The procedures are shown as a set of blocks that specify operations performed by one or more devices and are not necessarily limited to the orders shown for performing the operations by the respective blocks. In portions of the following discussion, reference is made to FIGS. 1-7. FIG. 8 is a flow diagram depicting a procedure in an example implementation for fluid simulation using a reduced space representation.

Input data associated with a fluid simulation is received (block 802). The graphics module 110 receives the input data 116. Examples of the input data include data associated with fluid simulations, fluid properties, domain size, domain resolution, initial velocity distributions, initial density distributions, external forces, boundary conditions, obstacle configurations, and so forth. The graphics module 110 communicates the input data 116 to the simulation module 202, simulation module 202, and the force module 204. In some examples, the simulation module 202 receives the input data 116.

Generation of a fluid simulation is initiated based on the input data received (block 804). The simulation module 202 receives the input data 116. The simulation module 202 is configured to perform operations pertaining to simulations (e.g., fluid simulations), examples of which include receiving data pertaining to fluid simulations (e.g., the input data 116), processing data pertaining to fluid simulations, initiating generating of the simulation output 118 (e.g., fluid simulations), generating simulation output 118 (e.g., fluid simulations), modifying fluid simulations, leveraging the simulation data 112, computing control forces for fluid simulations, representing velocity fields, rendering fluid simulations, and outputting fluid simulations. Responsive to receiving the input data 116, the simulation module 202 initiates generation of a fluid simulation based on the input data 116.

A reduced space velocity field representation is constructed that is derived from the input data (block 806). Based on the input data 116, the simulation module 202 constructs a reduced space representation of a velocity field of the fluid simulation 214, e.g., a “reduced space velocity field representation 206.” In some examples, the simulation module 202 leverages a governing equation of the simulation data 112—

$$u = {\sum }_{k = 1}^{r} {w}_{k} {ψ}^{k} = U w$$

—to construct the reduced space velocity field representation 206 using a Laplacian eigenfunction basis.

$$u = {\sum }_{k = 1}^{r} {w}_{k} {ψ}^{k} = U w$$

defines how the velocity field u is represented in a reduced dimensional space. Instead of storing velocity values at every grid point in full space, the simulation module 202 expresses the velocity field as a weighted sum of basis functions ψ^{k}. In some examples, the basis functions are Laplacian eigenfunctions.

At least one control force is computed based on the input data and the reduced space velocity field representation (block 808). The force module 204 receives the reduced space velocity field representation 206 from the simulation module 202 and the input data 116 from the graphics module 110. The force module 204 is configured to perform operations pertaining to control forces for fluid simulations, including computing an optimal number of control forces for shaping the fluid simulation, computing one or more control forces (e.g., at least one control force 208), and so forth. The force module 204 computes at least one control force 208 based on the input data 116 and the reduced space velocity field representation 206. In some examples, the force module 204 computes the control forces 208 (e.g., f^{t}) by minimizing an objective function that configures the fluid simulation to follow user-defined keyframes while maintaining physical accuracy:

$$φ ( f , q ) = {k}_{s} {\sum }_{t = 0}^{n} {‖ {f}^{t} ‖}^{2} + {k}_{w} {\sum }_{t ∈ {K}_{w}} {‖ {w}^{t} - {w}^{t *} ‖}^{2} + {k}_{d} {\sum }_{t ∈ {K}_{d}} {‖ {a}^{t} - {a}^{t *} ‖}^{2} .$$

The reduced space velocity field representation is modified by using the at least one control force (block 810). The simulation module 202 receives the at least one control force 208 from the force module 204 of FIG. 2A. The simulation module 202 modifies the reduced space velocity field representation 206 by applying the at least one control force 208. In some examples, the simulation module 202 modifies the reduced space velocity field representation 206 by modifying the weight coefficients with the at least one control force, which modify the reduced space velocity field representation 206.

The fluid simulation is rendered for display (block 812). The simulation module 202 communicates processed simulation data 212 corresponding to the fluid simulation 214, the reduced space velocity field representation 206, and the at least one control force 208 to the display module 210. The display module 210 receives the processed simulation data 212 from the simulation module 202. The display module 210 is configured to perform operations pertaining to rendering and displaying fluid simulation content, such as the fluid simulation 214, the simulation output 118, the reduced space velocity field representation 206, or the at least one control force 208. Based on the processed simulation data 212, the display module 210 renders the simulation output 118 including the fluid simulation 214.

The fluid simulation is presented for display (block 814) in a user interface. The display module 210 communicates the simulation output 118 including the fluid simulation 214 to the display device 106 for display.

### Example System and Device

FIG. 9 illustrates an example system 900 that includes an example computing device that is representative of one or more computing systems and/or devices that are usable to implement the various techniques described herein. This is illustrated through inclusion of the graphics module 110. The computing device 902 includes, for example, a server of a service provider, a device associated with a client (e.g., a client device), an on-chip system, and/or any other suitable computing device or computing system.

The example computing device 902 as illustrated includes a processing system 904, one or more computer-readable media 906, and one or more I/O interfaces 908 that are communicatively coupled, one to another. Although not shown, the computing device 902 further includes a system bus or other data and command transfer system that couples the various components, one to another. For example, a system bus includes any one or combination of different bus structures, such as a memory bus or memory controller, a peripheral bus, a universal serial bus, and/or a processor or local bus that utilizes any of a variety of bus architectures. A variety of other examples are also contemplated, such as control and data lines.

The processing system 904 is representative of functionality to perform one or more operations using hardware. Accordingly, the processing system 904 is illustrated as including hardware elements 910 that are configured as processors, functional blocks, and so forth. This includes example implementations in hardware as an application specific integrated circuit or other logic device formed using one or more semiconductors. The hardware elements 910 are not limited by the materials from which they are formed or the processing mechanisms employed therein. For example, processors are comprised of semiconductor(s) and/or transistors (e.g., electronic integrated circuits (ICs)). In such a context, processor-executable instructions are, for example, electronically-executable instructions.

The computer-readable media 906 is illustrated as including memory/storage 912. The memory/storage 912 represents memory/storage capacity associated with one or more computer-readable media. In one example, the memory/storage 912 includes volatile media (such as random access memory (RAM)) and/or nonvolatile media (such as read only memory (ROM), Flash memory, optical disks, magnetic disks, and so forth). In another example, the memory/storage 912 includes fixed media (e.g., RAM, ROM, a fixed hard drive, and so on) as well as removable media (e.g., Flash memory, a removable hard drive, an optical disc, and so forth). The computer-readable media 906 is configurable in a variety of other ways as further described below.

Input/output interface(s) 908 are representative of functionality to allow a user to enter commands and information to computing device 902, and also allow information to be presented to the user and/or other components or devices using various input/output devices. Examples of input devices include a keyboard, a cursor control device (e.g., a mouse), a microphone, a scanner, touch functionality (e.g., capacitive or other sensors that are configured to detect physical touch), a camera (e.g., which employs visible or non-visible wavelengths such as infrared frequencies to recognize movement as gestures that do not involve touch), and so forth. Examples of output devices include a display device (e.g., a monitor or projector), speakers, a printer, a network card, tactile-response device, and so forth. Thus, the computing device 902 is configurable in a variety of ways as further described below to support user interaction.

Various techniques are described herein in the general context of software, hardware elements, or program modules. Generally, such modules include routines, programs, objects, elements, components, data structures, and so forth that perform particular tasks or implement particular abstract data types. The terms “module,” “functionality,” and “component” as used herein generally represent software, firmware, hardware, or a combination thereof. The features of the techniques described herein are platform-independent, meaning that the techniques are implementable on a variety of commercial computing platforms having a variety of processors.

Implementations of the described modules and techniques are storable on or transmitted across some form of computer-readable media. For example, the computer-readable media includes a variety of media that is accessible to the computing device 902. By way of example, and not limitation, computer-readable media includes “computer-readable storage media” and “computer-readable signal media.”

“Computer-readable storage media” refers to media and/or devices that enable persistent and/or non-transitory storage of information in contrast to mere signal transmission, carrier waves, or signals per se. Thus, computer-readable storage media refers to non-signal bearing media. The computer-readable storage media includes hardware such as volatile and non-volatile, removable and non-removable media and/or storage devices implemented in a method or technology suitable for storage of information such as computer readable instructions, data structures, program modules, logic elements/circuits, or other data. Examples of computer-readable storage media include, but are not limited to, RAM, ROM, EEPROM, flash memory or other memory technology, CD-ROM, digital versatile disks (DVD) or other optical storage, hard disks, magnetic cassettes, magnetic tape, magnetic disk storage or other magnetic storage devices, or other storage device, tangible media, or article of manufacture suitable to store the desired information and which are accessible to a computer.

“Computer-readable signal media” refers to a signal-bearing medium that is configured to transmit instructions to the hardware of the computing device 902, such as via a network. Signal media typically embodies computer-readable instructions, data structures, program modules, or other data in a modulated data signal, such as carrier waves, data signals, or another transport mechanism. Signal media also includes any information delivery media. The term “modulated data signal” means a signal that has one or more of its characteristics set or changed in such a manner as to encode information in the signal. By way of example, and not limitation, communication media include wired media such as a wired network or direct-wired connection, and wireless media such as acoustic, RF, infrared, and other wireless media.

As previously described, hardware elements 910 and computer-readable media 906 are representative of modules, programmable device logic and/or fixed device logic implemented in a hardware form that is employable in some embodiments to implement at least some aspects of the techniques described herein, such as to perform one or more instructions. Hardware includes components of an integrated circuit or on-chip system, an application-specific integrated circuit (ASIC), a field-programmable gate array (FPGA), a complex programmable logic device (CPLD), and other implementations in silicon or other hardware. In this context, hardware operates as a processing device that performs program tasks defined by instructions and/or logic embodied by the hardware as well as a hardware utilized to store instructions for execution, e.g., the computer-readable storage media described previously.

Combinations of the foregoing are also employable to implement various techniques described herein. Accordingly, software, hardware, or executable modules are implementable as one or more instructions and/or logic embodied on some form of computer-readable storage media and/or by one or more hardware elements 910. For example, the computing device 902 is configured to implement particular instructions and/or functions corresponding to the software and/or hardware modules. Accordingly, implementation of a module that is executable by the computing device 902 as software is achieved at least partially in hardware, e.g., through use of computer-readable storage media and/or hardware elements 910 of the processing system 904. The instructions and/or functions are executable/operable by one or more articles of manufacture (for example, one or more computing devices 902 and/or processing systems 904) to implement techniques, modules, and examples described herein.

The techniques described herein are supportable by various configurations of the computing device 902 and are not limited to the specific examples of the techniques described herein. This functionality is also implementable entirely or partially through use of a distributed system, such as over a “cloud” 914 as described below.

The cloud 914 includes and/or is representative of a platform 916 for resources 918. The platform 916 abstracts underlying functionality of hardware (e.g., servers) and software resources of the cloud 914. For example, the resources 918 include applications and/or data that are utilized while computer processing is executed on servers that are remote from the computing device 902. In some examples, the resources 918 also include services provided over the Internet and/or through a subscriber network, such as a cellular or Wi-Fi network.

The platform 916 abstracts the resources 918 and functions to connect the computing device 902 with other computing devices. In some examples, the platform 916 also serves to abstract scaling of resources to provide a corresponding level of scale to encountered demand for the resources that are implemented via the platform. Accordingly, in an interconnected device embodiment, implementation of functionality described herein is distributable throughout the system 900. For example, the functionality is implementable in part on the computing device 902 as well as via the platform 916 that abstracts the functionality of the cloud 914.

Although implementations of systems for fluid simulation using a reduced space representation have been described in language specific to structural features and/or methods, it is to be understood that the appended claims are not necessarily limited to the specific features or methods described. Rather, the specific features and methods are disclosed as example implementations of systems for fluid simulation using a reduced space representation, and other equivalent features and methods are intended to be within the scope of the appended claims. Further, various different examples are described and it is to be appreciated that each described example is implementable independently or in connection with one or more other described examples.

What is claimed is:

1. A method comprising:
receiving, by a processing device, input data describing a fluid simulation to be generated;
generating, by the processing device, a reduced space representation of a velocity field of the fluid simulation based on the input data;
modifying, by the processing device, the reduced space representation of the velocity field based on a control force defined by the input data; and
generating, by the processing device, the fluid simulation for display in a user interface based on the reduced space representation of the velocity field as modified.

2. The method of claim 1, wherein the input data includes one or more simulation parameters, one or more keyframes, or one or more fluid simulation parameters.

3. The method of claim 1, wherein the reduced space representation is configured using one or more basis functions.

4. The method of claim 3, wherein the one or more basis functions are configured as Laplacian eigenfunctions.

5. The method of claim 1, further comprising:
receiving, by the processing device, a user input specifying an additional modification to the fluid simulation;
generating, by the processing device, an updated fluid simulation by updating the reduced space representation of the velocity field as modified; and
presenting, by the processing device, the updated fluid simulation for display in the user interface.

6. The method of claim 5, wherein the receiving of the user input and the generating of the updated fluid simulation are performed in real time.

7. The method of claim 1, wherein the generating the fluid simulation includes computing an advection tensor, the advection tensor defining nonlinear interactions between Laplacian eigenfunctions representing the velocity field.

8. The method of claim 1, wherein the modifying of the reduced space representation of the velocity field includes advancing the reduced space representation of the velocity field in time using an implicit trapezoidal integration.

9. The method of claim 1, wherein the generating the fluid simulation includes applying a damping function to the reduced space representation of the velocity field as modified.

10. The method of claim 1, wherein:
the input data includes a first digital artwork and a second digital artwork; and
the fluid simulation includes an interpolation between the first digital artwork and the second digital artwork.

11. The method of claim 1, wherein the generating of the fluid simulation includes encoding a density field of the reduced space representation.

12. The method of claim 1, wherein the control force is computed as a gradient of an objective function.

13. The method of claim 1, wherein the user interface includes one or more user-adjustable controls configurable to update the fluid simulation.

14. A system comprising:
a memory component; and
one or more processing devices coupled to the memory component, the one or more processing devices to perform operations including:
receiving a fluid simulation input specifying a fluid simulation modification for a fluid simulation generated using a reduced space representation of a velocity field;
generating an updated fluid simulation based on the fluid simulation input, in which the generating includes:
generating one or more control forces; and
modifying the reduced space representation of the velocity field of the fluid simulation by using the one or more control forces; and
presenting the updated fluid simulation for display in a user interface.

15. The system of claim 14, wherein the fluid simulation input includes at least one of a keyframe constraint, a pathline constraint, a velocity constraint, an obstacle constraint, an external force constraint, a vorticity constraint, a symmetry constraint, a density constraint, or an interactive constraint.

16. The system of claim 14, wherein the modifying the reduced space representation of the velocity field includes adjusting one or more weights within the reduced space representation.

17. The system of claim 14, wherein the generating of the updated fluid simulation includes frequency-based filtering.

18. The system of claim 14, wherein the fluid simulation input includes data describing an obstacle constraint and the modifying of the velocity field adheres to the data describing the obstacle constraint at least in part by using a soft constraint penalty term.

19. One or more computer-readable storage media comprising instructions stored thereon that, responsive to execution by a computing device, causes the computing device to perform operations including:
receiving, by a processing device, input data describing a fluid simulation to be generated;
generating, by the processing device, a reduced space representation of a velocity field of the fluid simulation based on the input data;
modifying, by the processing device, the reduced space representation of the velocity field based on a control force defined by the input data; and
generating, by the processing device, the fluid simulation for display in a user interface based on the reduced space representation of the velocity field as modified.

20. The one or more computer-readable storage media of claim 19, wherein the input data includes one or more simulation parameters, one or more keyframes, or one or more fluid simulation parameters.
